(19) United States
(12) Patent Application Publication
(10) Pub. No.: US 2026/0311786 A1
(43) Pub. Date: Oct. 8, 2026

(54) 3D EFUSE WITH DATA POISON

(71) Applicants: Advanced Micro Devices, Inc., Santa Clara, CA (US); ATI Technologies ULC, Markham (CA)

(72) Inventors: Zheng GONG, Toronto (CA); Chunjun XU, Shanghai (CN); Dapeng ZHOU, Markham (CA)

(21) Appl. No.: 19/190,004

(22) Filed: Apr. 25, 2025

(30) Foreign Application Priority Data
Apr. 4, 2025 (WO) PCT/CN2025/087372

(51) Int. Cl. G11C 17/16; G11C 17/18; H10B 20/25

(52) U.S. Cl. CPC G11C 17/165; G11C 17/18; H10B 20/25

(57) ABSTRACT

A 3-D EFuse with data poison circuit that includes a re-programmable persistent storage cell having an electronic fuse and an electronic anti-fuse, where the electronic fuse and the electronic anti-fuse set a resistance of the re-programmable fuse circuit to a first resistance, the electronic anti-fuse is programmable to change the resistance of the re-programmable fuse circuit from the first resistance to a second resistance, and the electronic fuse is programmable to change the resistance of the re-programmable fuse circuit from the second resistance to a third resistance. A sensor circuit may compare the resistance of the re-programmable persistent storage cell to a reference resistance. A controller may determine a state of the re-programmable persistent storage cell based on an output of the sensor circuit. The electronic anti-fuse and the electronic fuse may include regions of multiple metal layers of an IC device.

### TECHNICAL FIELD

Examples of the present disclosure generally relate to electronic fuses and, more particularly, to a re-programmable electronic fuse.

### BACKGROUND

With the increasing complexity and application specific chip configurations, data invasive attacks are also increasing. For example, a dynamic random-access memory (DRAM) cell includes a capacitor and a transistor. The state of the DRAM cell is determined by the capacitor status (charged or discharged). Contents of DRAM cells may be protected by algorithms (e.g., encryption). In addition, in the event of a suspected security breach, contents of DRAM cells may be over-written. Capacitor charge may, however, dissipate over time, so periodical data refreshing may be required. Row hammer takes advantage of the leakage current from DRAM cells, by the voltage fluctuation caused by frequent selected row activations, which causes higher than normal discharge rates in capacitors belonging to nearby memory cells, will eventually alter the content in nearby memory cells.

An integrated circuit device may include a one-time-programmable (OTP) persistent storage cell, which does not require refreshing. A OTP persistent storage cell may include an electronic fuse or an anti-fuse, and a sensing circuit may determine whether the electronic fuse or an anti-fuse is in an un-programmed state or a programmed state. Once programmed, electronic fuse or an anti-fuse cannot be electronically un-programmed or electronically erased, which renders an OTP persistent storage device subject to malicious attack (e.g., malicious reading).

### SUMMARY

Techniques for re-programmable electronic fuses (e.g., a 3-dimensional E Fuse with data poison) are described. One example is an integrated circuit (IC) device that includes a re-programmable persistent storage cell comprising an electronic fuse and an electronic anti-fuse, where the electronic fuse and the electronic anti-fuse set a resistance of the re-programmable persistent storage cell to a first resistance, the electronic anti-fuse is programmable to change the resistance of the re-programmable persistent storage cell from the first resistance to a second resistance, and the electronic fuse is programmable to change the resistance of the re-programmable persistent storage cell from the second resistance to a third resistance.

Another example is an IC device that includes a row of re-programmable persistent storage cells, each including an electronic anti-fuse, an electronic fuse, and a fuse programming circuit that programs the electronic fuse. The IC device further includes an anti-fuse programming circuit that programs the electronic anti-fuses of the row of re-programmable persistent storage cells, where the electronic fuses and the electronic anti-fuses set resistances of the respective re-programmable persistent storage cells to a first resistance, where the electronic anti-fuses are programmable to change the resistances of the re-programmable persistent storage cells from the first resistance to a second resistance, and where the electronic fuses are programmable to change the resistances of the re-programmable persistent storage cells from the second resistance to a third resistance.

Another example is a method that includes programming an electronic anti-fuse of a re-programmable persistent storage cell to change a resistance of the re-programmable persistent storage cell from a first resistance to a second resistance, and programming an electronic fuse of the re-programmable persistent storage cell to change the resistance of the re-programmable persistent storage cell from a second resistance to a third resistance.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 depicts an integrated circuit (IC) device that includes a re-programmable persistent storage circuit, according to an embodiment.

FIG. 2 depicts features of a sensor circuit of the IC device, according to an embodiment.

FIG. 3 depicts the IC device with a row or word of fuse cells, according to an embodiment.

FIG. 4 depicts the IC device with multiple rows or words of fuse cells, according to an embodiment.

FIG. 5 is a schematic of the re-programmable persistent storage circuit, according to an embodiment.

FIG. 6 is a schematic of the sensor circuit, according to an embodiment.

FIG. 7 depicts a layout of the IC device, according to an embodiment.

FIG. 8 depicts a method of programming and re-programming (e.g., poisoning) a fuse cell, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe a 3-dimensional electronic fuse cell with data poison (i.e., re-programmability). The 3-dimensional electronic fuse cell with data poison may be implemented as a re-programmable persistent data storage cell.

A persistent storage cell having only an electronic fuse or an electronic anti-fuse cannot be erased or over-written, and is thus susceptible to attack (e.g., unauthorized reading).

A re-programmable persistent data storage cell, as disclosed herein, includes one or more electronic anti-fuses and one or more electronic fuses, such that with the cell may be electronically re-programmable (i.e., erasable). Re-programmability may be useful to preclude an attacker from reading contents of the storage cell.

The electronic anti-fuse(s) and the electronic fuse(s) may include regions of multiple metal layers of an IC device (i.e., a stack-on-stack programming bit cell), which may reduce a number of fabrication masks. Vertical stacking may avoid a need for data redundancy (i.e., no extra area burnt). Also it improves the speed by using fewer clock cycles.

An array of re-programmable persistent data storage cells may include per-wordline programming controls, which may reduce the number of clock cycles, which may improve speed.

A re-programmable persistent data storage cell, as disclosed herein, may include two-time-programmable (TTP) fuse cell. Re-programmable persistent data storage cells are not, however, limited to TTP fuse cells.

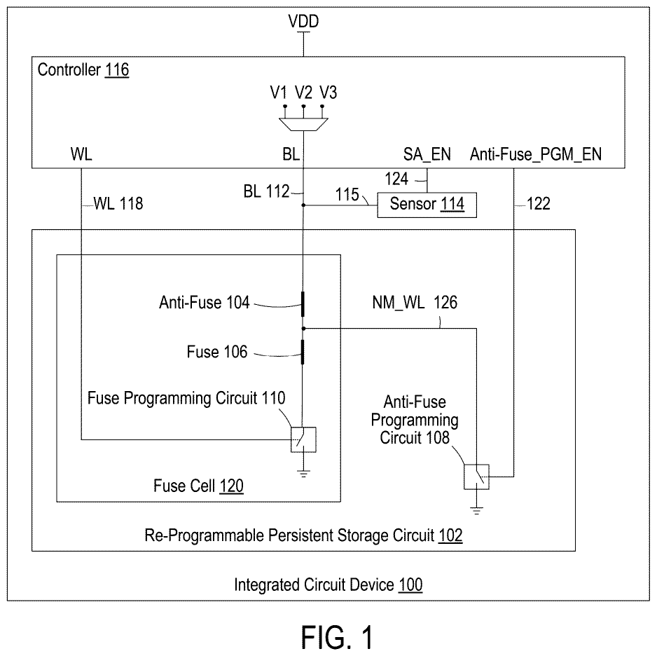

FIG. 1 depicts an integrated circuit (IC) device 100 that includes a re-programmable persistent storage circuit 102, according to an embodiment. In the example of FIG. 1, re-programmable persistent storage circuit 102 includes an electronic anti-fuse (anti-fuse) 104, an electronic fuse (fuse) 106, an anti-fuse programming circuit 108, and a fuse programming circuit 110. Anti-fuse programming circuit 108 and fuse programming circuit 110 are depicted as switches, which may represent transistors, examples of which are provided further below. Anti-fuse 104, fuse 106, and fuse programming circuit 110 may be collectively referred to as a re-programmable persistent storage cell, or a fuse cell 120.

Prior to programming, anti-fuse 104 has a high resistance (e.g., approaching or equal to an open circuit). Anti-fuse 104 may include a pair of metal strips separated by a layer of silicon dioxide. When an operating voltage V1 is applied to a bitline (BL) 112, the layer of silicon dioxide substantially prevents current flow between the two metal strips. Anti-fuse 104 may be programmed (i.e., converted to a short circuit) by applying an anti-fuse programming voltage V2 across the metal strips for a period of time sufficient to break-down the layer of silicon dioxide, such that the metal strips contact one another to form a short circuit.

Conversely, prior to programming, fuse 106 has a low resistance (i.e., approaching or equal to a short circuit). Fuse 106 may include one or more metal strips and/or a metal-filled via. Fuse 106 may be programmed (i.e., converted to an open circuit), subsequent to programming anti-fuse 104, by applying a fuse programming voltage V3 to fuse 106 for a time sufficient to sever the metal strip(s) and/or metal-filled via, thereby converting fuse 106 to an open circuit.

Table 1 summarizes states of fuse cell 120.

TABLE 1

| | | | Fuse Cell |
|---|---|---|---|
| Fuse Cell 120 | Anti-Fuse 104 | Fuse 106 | Resistance |
| Un-Programmed State | ~Open Circuit | ~Short Circuit | High |
| First Programmed State | ~Short Circuit | ~Short Circuit | Low |
| Second Programmed State | ~Short Circuit | ~Open Circuit | High |

IC device 100 may further include a sensor circuit (sensor) 114 to determine the state of re-programmable persistent storage circuit 102. In an example, sensor 114 compares a resistance of fuse cell 120 to a reference resistance of sensor 114. IC device 100 may further include a controller 116 to provide controls to re-programmable persistent storage circuit 102 and sensor 114.

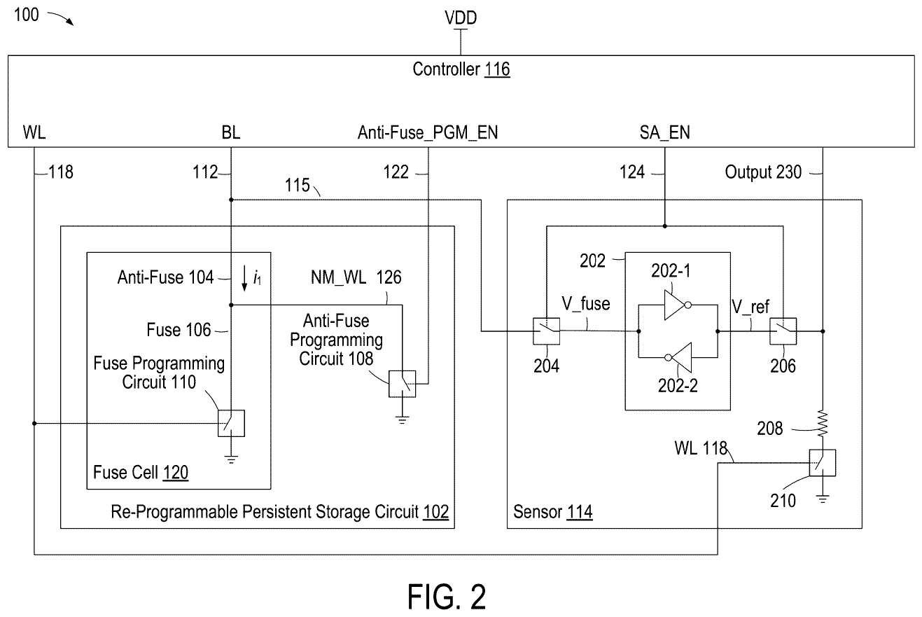

FIG. 2 depicts IC device 100, according to an embodiment. In the example of FIG. 2, sensor 114 includes cross-coupled inverters 202-1 and 202-2 (collectively, cross-coupled inverters 202), switch circuits 204, 206, and 210 (e.g., transistors), and a reference resistor 208. To place sensor 114 in a sensing mode, controller 116 activates enable controls SA_EN and a wordline (WL) 118. In the sensing mode, switch circuits 204, 206, and 210 are closed, to provide a path from a bitline (BL) 112 to a reference voltage (e.g., ground). A reference resistance of sensor 114 may include a sum of resistances of reference resistor 208 and switch circuit 210.

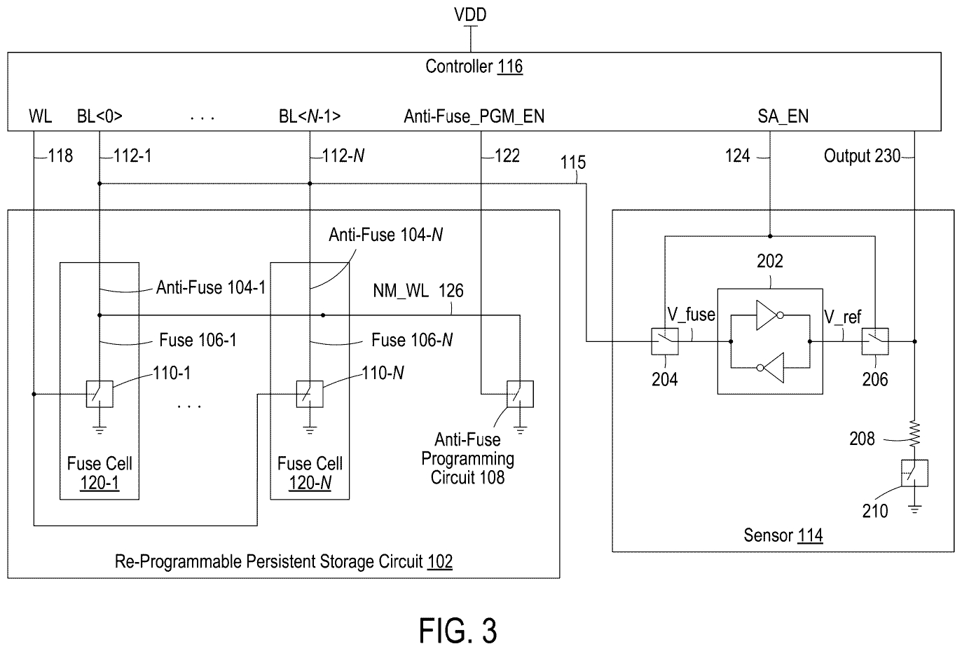

FIG. 3 depicts IC device 100 in which re-programmable persistent storage circuit 102 includes a row or word of N fuse cells 120-1 through 120-N, according to an embodiment. In the example of FIG. 3, fuse cells 120-1 through 120-N share anti-fuse programming circuit 108.

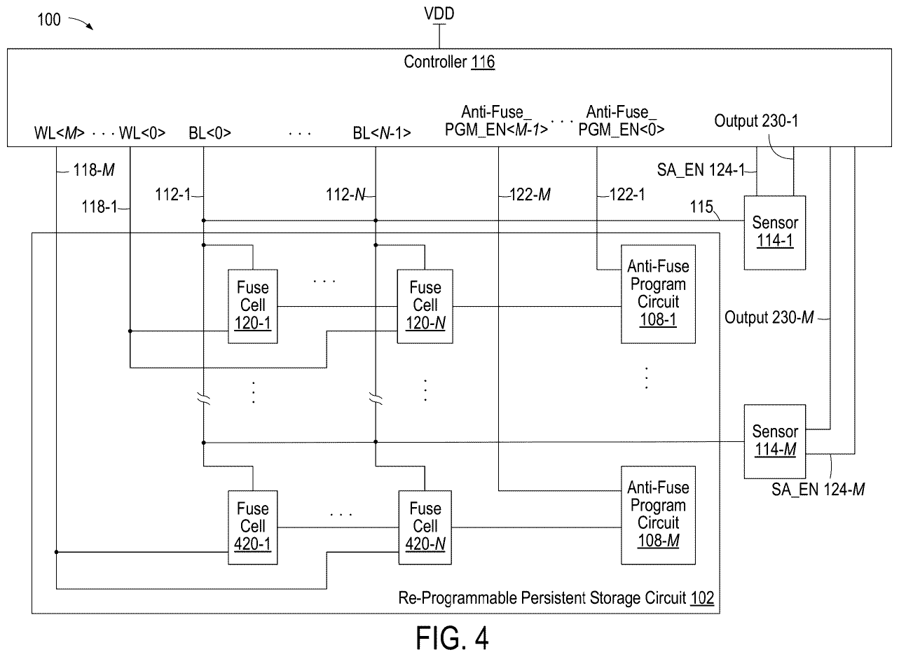

FIG. 4 depicts IC device 100 in which re-programmable persistent storage circuit 102 includes M rows or words of N fuse cells, according to an embodiment. In the example of FIG. 4, a first row includes fuse cells 120-1 through 120-N and anti-fuse programing circuit 108-1. A last row includes fuse cells 420-1 through 420-N and anti-fuse programing circuit 108-M. IC device 100 may further include a sensor for each row, depicted here as sensors 114-1 through 114-M.

In the examples of FIGS. 3 and 4, there is a single anti-fuse programming circuit 108 per row of fuse cells, which may reduce complexity, reduce area, and/or improve yield of IC device 100. In another example, each fuse cell may be provided with a respective anti-fuse programming circuit 108.

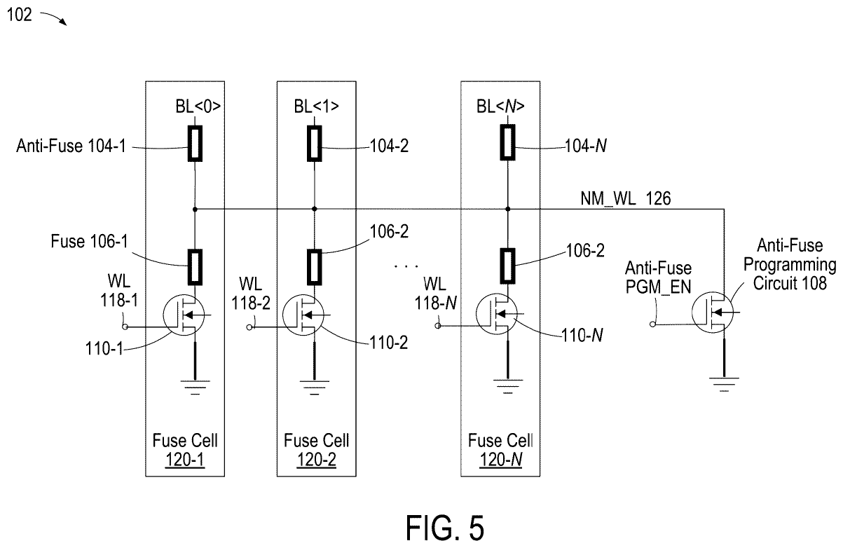

FIG. 5 is a schematic of re-programmable persistent storage circuit 102, according to an embodiment. In the example of FIG. 5, fuse programming circuits 110-1 through 110-N, and anti-fuse programming circuit 108, are depicted as N-type metal-oxide semiconductor field-effect transistors (MOSFETs). Fuse programming circuits 110 are not, however, limited to N-type MOSFETs.

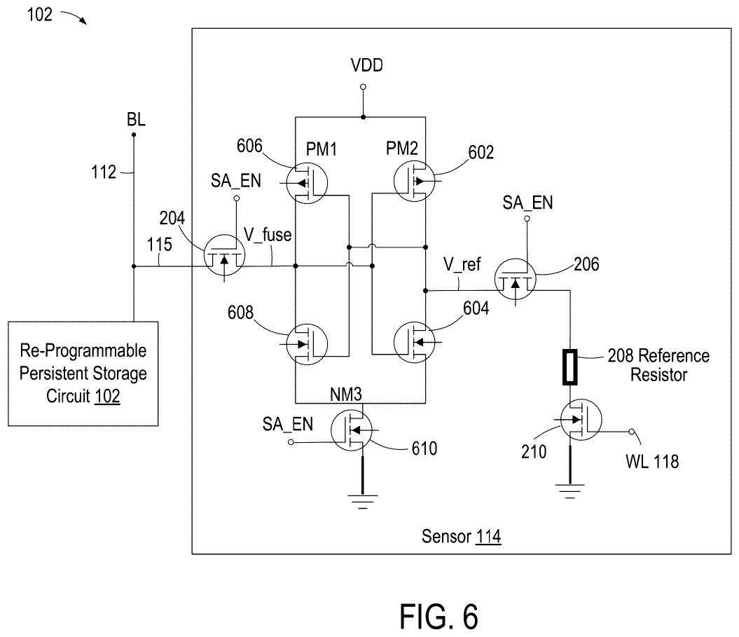

FIG. 6 is a schematic of sensor 114, according to an embodiment. In the example of FIG. 6, switch circuits 204, 206, and 210 are depicted as N-type MOSFETs. Further in FIG. 6, inverter 202-1 includes P-type MOSFET 602 and N-type MOSFET 604. Inverter 202-2 includes P-type MOSFET 606 and N-type MOSFET 608. Sensor 114 further includes a pull-down circuit 610, depicted here as an N-type MOSFET.

Table 2 provides a summary of states of controls for re-programmable persistent storage circuit 102.

TABLE 2

| | | Anti-Fuse | Fuse |
|---|---|---|---|
| Controls | Sense Mode | Program Mode | Program Mode |
| Anti-Fuse_PGM_EN | Inactive (e.g., | Active (e.g., | Inactive (e.g., |
| 122 | low) | high) | low) |
| WL 118 | Active (e.g., | Inactive (e.g., | Active (e.g., |
| | high) | low) | high) |
| BL 112 | V1 | V2 | V3 |
| SA_EN 124 | Active (e.g., | Inactive (e.g., | Inactive (e.g., |
| | high) | low) | low) |

In Table 2, V1 and “active” may correspond to operating voltage VDD. Operating voltage VDD may be less than voltages V2 and V3. Voltage V2 may be above a threshold or breakdown voltage of anti-fuse 104. Voltage V3 may be above a threshold or breakdown voltage of fuse 106. Voltages V2 and V3 may equal one another or may differ from one another. In an example, voltage V2 is greater than voltage V3 to protect anti-fuse 104 from damage when programming fuse 106. In FIG. 5, the transistor of anti-fuse programming circuit 108 may be larger than the transistors of fuse programming circuits 110-1 through 110-N. Anti-fuse 104 is to be programmed prior to programming fuse 106. Anti-fuse 104 may protect fuse 106 from reading.

Table 3 provides a summary of relative resistances and sensor outputs 230 for states of fuse cell 120.

TABLE 3

| Fuse Cell State | Relative Resistances | Sensor Output 230 |
|---|---|---|
| Un-Programmed | R_{Fuse Cell} > R_{Ref} | Low (Logic 0) |
| Programmed | R_{Fuse Cell} < R_{Ref} | High (Logic 1) |
| Re-Programmed (i.e., | R_{Fuse Cell} > R_{Ref} | Low (Logic 0) |
| poisoned) | | |

Sensor output 230 may serve as an indication of whether the fuse cell is programmed as a logic 1 or a logic 0.

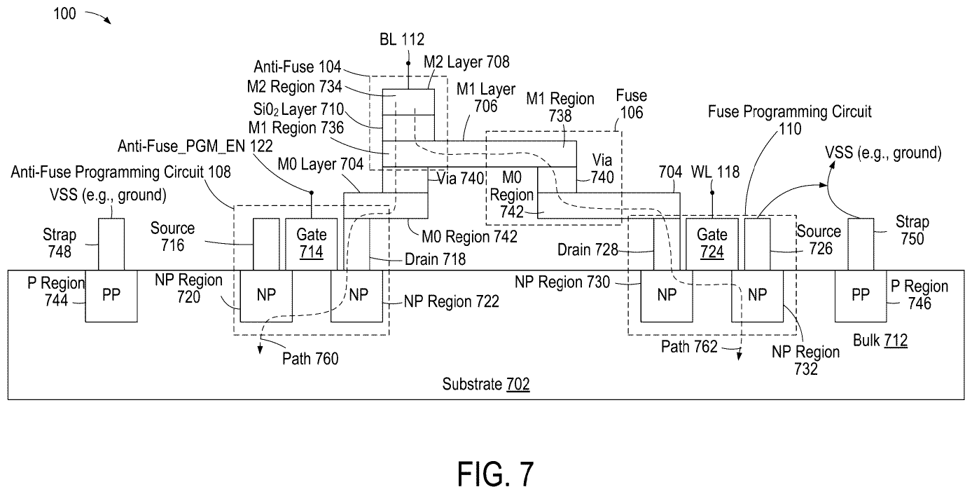

FIG. 7 depicts a layout of IC device 100, according to an embodiment. In the example of FIG. 7, IC device 100 include a substrate 702, metal layers M0 704, M1 706, and M2 708, and a silicon dioxide layer 710 between metal layers M1 706 and M2 708. Substrate 702 may further include a bulk region 712, P regions 744 and 746, and/or straps 748 and 750.

Anti-fuse 104 includes a region 734 of metal layer M2, a region 736 of metal layer M1, and silicon dioxide layer 710. Anti-fuse programming circuit 108 includes a transistor having a gate 714, a source 716, a drain 718, and NP regions 720 and 722. Gate 714 receives anti-fuse_PGM_EN 122. During programming of anti-fuse 104, when/as silicon dioxide layer 710 breaks down, current may follow a path 760, from BL 112, through M2 region 734, silicon dioxide layer 710, M1 region 736, a metal-filled via 740, a region 742 of M0 layer 704, drain 718, source 716, and substrate 702.

Fuse 106 includes a region 738 of metal layer M1, a metal-filled via 740, and a region 742 of metal layer M0 704. Fuse programming circuit 110 includes a transistor having a gate 724, a source 726, a drain 728, and NP regions 730 and 732. Gate 724 receives WL 118. At the beginning of programming of fuse 106 (i.e., prior to breakdown of fuse 106), current may follow a path 762, from BL 112, through M2 region 734, M1 region 736, M1 region 738, a metal-filled via 740, a region 742 of M0 layer 704, drain 728, source 726, and substrate 702. A size of M1 region 738, M0 region 742, and/or metal-filled via 740 may determine a region at which fuse 106 breaks down during programming of fuse 106.

In the example of FIG. 7, anti-fuse 104 and fuse 106 share M1 layer 706, which reduces the number of masks needed during fabrication. In addition, anti-fuse 104 and fuse 106 are vertically stacked. As a result, there is no need for a redundancy array, no extra area is burnt, and fewer clock cycles are needed, thus improving speed.

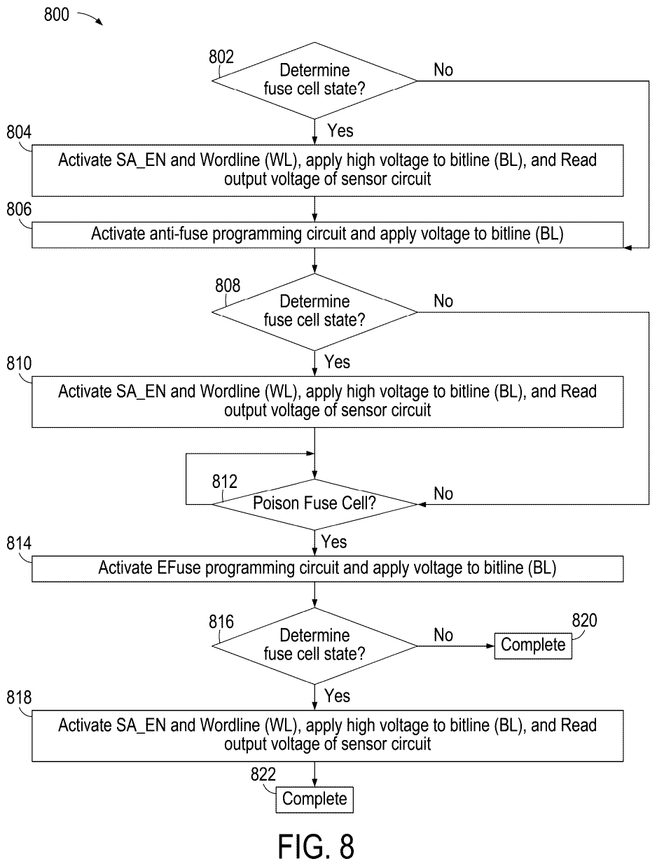

FIG. 8 depicts a method 800 of programming and re-programming (e.g., poisoning) a fuse cell, according to an embodiment. Method 800 is described below with reference to FIGS. 1 through 7. Method 800 is not, however, limited to the examples of any of FIGS. 1 through 7.

Method 800 may begin with fuse cell 120 in the un-programmed state.

At 802, controller 116 may determine the state of fuse cell 120 prior to programming fuse cell 120. This may be useful to determine whether the resistance of fuse cell 120 is greater than the reference resistance of sensor 114. If the relative resistances of fuse cell 120 and the reference resistance of sensor 114 is to be determined prior to programming fuse cell 120, processing proceeds to 804.

At 804, controller 116 activates sensor 114. In an example, controller 116 activates SA_EN and WL 118, applies operating voltage V1 to BL 112, and reads output 230 of sensor 114. As described further above, operating voltage V1 may be below a threshold or breakdown voltage at which silicon dioxide layer 710 (FIG. 7) breaks down due to electron migration.

When sensor 114 is active and voltage V1 is applied to bitline (BL) 112, no current flows through anti-fuse 104 (i.e., due to silicon dioxide layer 710), and BL 112 remains at voltage V1. In this state, a node V_fuse of cross-coupled inverters 202 is pulled up towards VDD, a node V_ref of cross-coupled inverters 202 is pulled down towards ground via reference resistor 208 and switch circuit 210, and cross-coupled inverters 202 maintain node V_fuse at VDD and node V_ref at ground due to contention (i.e., positive feedback). In this example, little or no current flows through reference resistor 208 and switch circuit 210, and sensor output 230 is pulled down towards ground (i.e., logic 0). After reading sensor output 230, controller 116 may de-activate SA_EN and WL 118, and may remove voltage V1 from BL 112.

At 806, controller 116 programs fuse cell 120 (i.e., converts anti-fuse 104 to a short circuit). In FIG. 2, controller 116 activates Anti-Fuse PGM_EN 122 to pull-down NM_WL 126 towards ground via anti-fuse programming circuit 108, and applies voltage V2 to BL 112 for a period of time. Voltage V2 may be above the threshold or breakdown voltage of silicon dioxide layer 710 (FIG. 7), such that silicon dioxide layer 810 breaks down due to electron migration, converting anti-fuse 104 to a short circuit.

In FIG. 3, controller 116 may program fuse cells 120-1 through 120-N, or a subset thereof, in a serial fashion, by serially applying the first voltage to respective ones of BLs 112-1 through 112-N. Controller 166 may program a subset of fuse cells 120-1 through 120-N, and may leave remaining ones of fuse cells 120-1 through 120-N un-programmed, to form a multi-bit word.

In FIG. 4, controller 116 may program one or more fuse cells in one or more of the M rows of fuse cells, in a serial fashion, by serially activating respective ones of WLs 118-1 through 118-M, and serially applying the first voltage to respective ones of BLs 112-1 through 112-N.

At 808, controller 116 may determine the state of fuse cell 120 subsequent to programming anti-fuse 104. This may be useful to verify that the resistance of fuse cell 120 is less than the reference resistance of sensor 114. If the state of fuse cell 120 is to be determined subsequent to programming fuse cell 120, processing proceeds to 810.

At 810, controller 116 activates sensor 114, such as described above with reference to 804. If fuse cell 120 is programmed (i.e., a short circuit) and sensor 114 is in the sensing mode, applying voltage V1 to BL 112 results in current flow from BL 112 to ground via anti-fuse 104, fuse 106, and fuse programming circuit 110, which pulls-down BL 112 and node V_fuse toward ground. In this situation, cross-coupled inverters 202 pull-down/maintain node V_fuse at ground and pull-up node V_ref and output 230 toward VDD due to contention (i.e., positive feedback). After reading sensor output 230, controller 116 may de-activate SA_EN and WL 118, and may remove voltage V1 from BL 112.

At 812, if fuse cell 120 is to be re-programmed (i.e., poisoned), processing proceeds to 814. Re-programming fuse cell 120 may be useful to render the programmed state of fuse cell 120 un-recoverable.

At 814, controller 116 re-programs (i.e., poisons) fuse cell 120 (i.e., converts fuse 106 to an open circuit), by programming fuse 106. In FIG. 2, controller 116 activates fuse programming circuit 110 to pull-down BL 112 towards ground via fuse programming circuit 110, and applies voltage V3 to BL 112 for a period of time sufficient to break-down fuse 106, which converts fuse 106 to an open circuit.

In FIG. 3 and/or FIG. 4, controller 116 may re-program all fuse cells, or all programmed fuse cells, such that all fuse cells are converted to open circuits. This ensures that the programmed state of re-programmable persistent storage circuit 102 is un-recoverable.

At 816, controller 116 may determine the state of fuse cell 120 subsequent to re-programming fuse cell 120. This may be useful to verify that the resistance of fuse cell 120 is greater than the reference resistance of sensor 114. If the state of fuse cell 120 is to be determined subsequent to re-programming fuse cell 120, processing proceeds to 816. Otherwise, processing may end at 820.

At 818, controller 116 places sensor 114 in the sensing mode, such as described above with reference to 804. If fuse 106 is programmed (i.e., an open circuit), applying a voltage to BL 112 does not result in current flow. Rather, programmed fuse 106 precludes current flow from BL 112 to ground via fuse 106. In this example, node V_fuse is pulled up toward VDD and node V_ref is pulled down towards ground by cross-coupled inverters 202, above and sensor output 230 is pulled up towards VDD (i.e., logic 1), such as described further above. After reading sensor output 230, controller 116 may de-activate SA_EN and WL 118, and may remove voltage V1 from BL 112.

If fuse 106 is programmed (i.e., an open circuit) and voltage V1 is applied to bitline (BL) 112, no current flows through fuse 106, and BL 112 (and node V_fuse) remains at voltage V1. In this state, cross-coupled inverters 202 pull up node V_fuse to VDD and pull-down node V_ref (and sensor output 230) towards ground (i.e., logic low). After reading sensor output 230, controller 116 may de-activate SA_EN and WL 118, and may remove voltage V1 from BL 112.

Processing may end at 822.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product.

Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as J ava, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC) device, comprising:
a re-programmable persistent storage cell comprising an electronic fuse and an electronic anti-fuse, wherein:
the electronic fuse and the electronic anti-fuse are configured to set a resistance of the re-programmable persistent storage cell to a first resistance;
the electronic anti-fuse is programmable to change the resistance of the re-programmable persistent storage cell from the first resistance to a second resistance; and
the electronic fuse is programmable to change the resistance of the re-programmable persistent storage cell from the second resistance to a third resistance.

2. The IC device of claim 1, wherein the first and third resistances are equal to one another.

3. The IC device of claim 1, wherein the electronic anti-fuse and the electronic fuse comprise regions of multiple metal layers of the IC device.

4. The IC device of claim 1, wherein:
the electronic anti-fuse comprises a first region of a first metal layer of the IC device, a first region of a second metal layer of the IC device, and a layer of silicon dioxide disposed between the first region of the first metal layer and the first region of the second metal layer; and
the electronic fuse comprises a second region of the second metal layer, a region of a third metal layer of the IC device, and a metal-filed via coupled to the second region of the second metal layer and to the region of the third metal layer.

5. The IC device of claim 1, further comprising:
a sensor circuit configured to compare the resistance of the re-programmable persistent storage cell to a reference resistance; and
a controller configured to determine a state of the re-programmable persistent storage cell based on an output of the sensor circuit.

6. The IC device of claim 1, further comprising:
an anti-fuse programming circuit configured to program the electronic anti-fuse;
a fuse programming circuit configured to program the electronic fuse; and
a controller configured to:
control the anti-fuse programming circuit to program the electronic anti-fuse; and
control the fuse programming circuit to program the electronic fuse subsequent to programming the electronic anti-fuse.

7. The IC device of claim 6, wherein:
the electronic anti-fuse is coupled to a bitline;
the electronic anti-fuse and the electronic fuse are series-connected with one another, between the bitline and the fuse programming circuit;
the anti-fuse programming circuit is coupled to a node between the electronic anti-fuse and the electronic fuse, and configured to couple the node to ground to program the electronic anti-fuse based on an anti-fuse program control from the controller; and
the fuse programming circuit is configured to couple the electronic fuse to a/the reference voltage to program the electronic fuse based on a wordline control from the controller.

8. The IC device of claim 7, wherein the controller is further configured to:
activate the anti-fuse program control and apply an anti-fuse programing voltage to the bitline for a first period of time to program the electronic anti-fuse; and
activate the wordline control and apply an electronic fuse programing voltage to the bitline for a second period of time to program the electronic fuse, subsequent to programming the electronic anti-fuse.

9. The IC device of claim 8, wherein the electronic fuse programing voltage differs from the anti-fuse programing voltage.

10. An integrated circuit (IC) device, comprising:
a first row of re-programmable persistent storage cells, each comprising an electronic anti-fuse, an electronic fuse, and a fuse programming circuit configured to program the electronic fuse; and
a first anti-fuse programming circuit configured to program the electronic anti-fuses of the first row of re-programmable persistent storage cells;
wherein:
the electronic fuses and the electronic anti-fuses are configured to set resistances of the respective re-programmable persistent storage cells to a first resistance;
the electronic anti-fuses are programmable to change the resistances of the re-programmable persistent storage cells from the first resistance to a second resistance; and
the electronic fuses are programmable to change the resistances of the re-programmable persistent storage cells from the second resistance to a third resistance.

11. The IC device of claim 10, further comprising:
a second row of re-programmable persistent storage cells, each comprising an electronic anti-fuse, an electronic fuse, and a fuse programming circuit configured to program the electronic fuse; and
a second anti-fuse programming circuit configured to program the electronic anti-fuses of the second row of re-programmable persistent storage cells.

12. The IC device of claim 10, wherein the electronic anti-fuses and the electronic fuses comprise regions of multiple metal layers of the IC device.

13. The IC device of claim 10, wherein:
the electronic anti-fuse of a first one of the re-programmable persistent storage cells comprises a first region of a first metal layer of the IC device, a first region of a second metal layer of the IC device, and a layer of silicon dioxide disposed between the first region of the first metal layer and the first region of the second metal layer; and
the electronic fuse of the first re-programmable persistent storage cell comprises a second region of the second metal layer, a region of a third metal layer of the IC device, and a metal-filed via coupled to the second region of the second metal layer and to the region of the third metal layer.

14. The IC device of claim 10, further comprising:
a sensor circuit configured to compare the resistances of the re-programmable persistent storage cells to a reference resistance; and
a controller configured to determine state of the re-programmable persistent storage cells based on respective outputs of the sensor circuit.

15. A method, comprising:
programming an electronic anti-fuse of a re-programmable persistent storage cell to change a resistance of the re-programmable persistent storage cell from a first resistance to a second resistance; and
programming an electronic fuse of the re-programmable persistent storage cell to change the resistance of the re-programmable persistent storage cell from a second resistance to a third resistance.

16. The method of claim 15, further comprising sensing a state of the re-programmable persistent storage cell, wherein the sensing comprises:
comparing the resistance of the re-programmable persistent storage cell to a reference resistance; and
outputting a logic state of the re-programmable persistent storage cell based on the comparing.

17. The method of claim 16, further comprising, performing the sensing at one or more of:
prior to the programming the electronic anti-fuse;
subsequent to the programming the electronic anti-fuse and prior to the programming the electronic anti-fuse; and
subsequent to the programming the electronic fuse.

18. The method of claim 15, wherein:
the programming the electronic anti-fuse comprises activating an anti-fuse program control and applying an anti-fuse programing voltage to a bitline for a first period of time; and
the programming the electronic anti-fuse comprises activating a wordline control and applying an electronic fuse programing voltage to the bitline for a second period of time, subsequent to the programming the electronic anti-fuse.

19. The method of claim 18, wherein the electronic fuse programing voltage is higher than the anti-fuse programing voltage.
